(19) United States
(12) Patent Application Publication
(10) Pub. No.: US 2017/0018634 A1
(43) Pub. Date: Jan. 19, 2017

(54) 3C-SiC IGBT

(71) Applicant: Anvil Semiconductors Limited, Warwickshire (GB)

(72) Inventor: Peter WARD, Cambridgeshire (GB)

(21) Appl. No.: 15/282,235

(22) Filed: Sep. 30, 2016

Related U.S. Application Data
(63) Continuation-in-part of application No. 14/350,916, filed on Apr. 10, 2014.

(30) Foreign Application Priority Data
Oct. 26, 2011 (GB) 1118502.2

(51) Int. Cl. H01L 29/739; H01L 21/265; H01L 29/10; H01L 29/16; H01L 29/66

(52) U.S. Cl. CPC H01L 29/7395; H01L 29/1608; H01L 29/66068; H01L 29/1095; H01L 21/26513

(57) ABSTRACT

We disclose herein a method of manufacturing a silicon carbide (SiC) based insulated gate bipolar transistor (IGBT), the IGBT comprising: a monocrystalline silicon substrate; a collector region of a first conductivity type disposed over the silicon substrate, wherein the collector region comprises a material comprising 3-step cubic silicon carbide (3C-SiC); a semiconductor drift region of a second conductivity type, opposite the first conductivity type, disposed on the collector region; a body region of the first conductivity type located within the semiconductor drift region; an emitter region of the second conductivity type located within the body region; a gate region placed above and in contact to the emitter region. The method comprising: providing the silicon substrate having a principal surface, wherein the silicon substrate is of the second conductivity type; doping the principal surface of the silicon substrate using an aluminium ion implant; and driving the aluminium ion implant into the silicon substrate to a predetermined depth under a predetermined temperature so that a heavily doped silicon region of the first conductivity type is formed near the principal surface within the silicon substrate.

### FIELD OF THE INVENTION

This invention relates to a 3 step cubic silicon carbide (3C SiC) based insulated gate bipolar transistor (IGBT).

### BACKGROUND TO THE INVENTION

So far there has been very little progress in any silicon carbide (SiC) technology towards building a high quality vertical 650V IGBT. There are several major challenges to be overcome, the first is to build an n-channel MOSFET with a very low channel resistance, this has to be complemented with a high minority carrier lifetime drift region to allow it to be conductivity modulated, and finally a p-type injector must be added to the “back-side” of the wafer to undertake that minority carrier injection.

The incumbent 4H-SiC technology fails in all three of the challenges above, it has an intrinsically high channel resistance due to traps just below the conduction band, minority carrier lifetimes are very low, and the natural n+ substrate does not allow the fabrication of a p-type injector. However, 3C-SiC/Si technology may facilitate solutions to these problems, we know that the MOS channel traps are avoided because of the positioning of the 3C-SiC conduction band, and PN diodes from Anvil Semiconductors Ltd. have already demonstrated good conductivity modulation.

In principle a p+ substrate can be used in hetero-epitaxy in place of the conventional n+ antimony (Sb) doped wafer in Anvil Semiconductor's technology, but realising a p+ substrate which is compatible with the typical 1370° C. epitaxy process is problematical, as is re-engineering the epitaxy and lattice miss-match compensating processes. It has been demonstrated that to make an IGBT we can simply take a MOSFET and change the n+Si wafer to a p+Si wafer. In practice it may be more difficult to that.

The basic problem is that the normal p-type dopant in Si is Boron, but this element has a very high vapour pressure above about 1000° C., and consequently it gives problems of unwanted background doping of the epitaxy reactor even for normal Si epitaxy, here the conventional solution is to seal the back of the wafer with silicon dioxide (SiO₂), but that would not work at typical 3C-SiC growth temperatures. Hence Boron contamination of SiC epitaxy reactors presents a major obstacle to this device structure.

### SUMMARY

According to one aspect of the present invention, there is provided a method of manufacturing a silicon carbide (SiC) based insulated gate bipolar transistor (IGBT), the IGBT comprising: a monocrystalline silicon substrate; a collector region of a first conductivity type disposed over the silicon substrate, wherein the collector region comprises a material comprising 3-step cubic silicon carbide (3C-SiC); a semiconductor drift region of a second conductivity type, opposite the first conductivity type, disposed on the collector region; a body region of the first conductivity type located within the semiconductor drift region; an emitter region of the second conductivity type the body region; a gate region placed above and in contact to the emitter region;
the method comprising:
   providing the silicon substrate having a principal surface, wherein the silicon substrate is of the second conductivity type;
   doping the principal surface of the silicon substrate using an aluminium ion implant; and
   driving the aluminium ion implant into the silicon substrate to a predetermined depth under a predetermined temperature so that a heavily doped silicon region of the first conductivity type is formed near the principal surface within the silicon substrate.

The principal surface of the silicon substrate may be doped using a heavy aluminium ion implant. The heavily Al doped silicon region within the silicon substrate helps to avoid the use of boron in the silicon substrate and thus avoids the problems as stated above.

The predetermined depth of the heavily doped silicon region from the principal surface into the silicon substrate may be at least about 100 μm.

The predetermined depth of the heavily doped silicon region from the principal surface into the silicon substrate may be at least about 150 μm.

The predetermined temperature under which the heavily doped silicon region within the silicon substrate may be grown is at least about 1300° C.

The aluminium ion implant dose may be about 10¹⁷ cm⁻².

The method may further comprise:
providing a masking layer on the principal surface of the silicon substrate, the masking layer having windows which expose corresponding regions of the heavily doped silicon region of the silicon substrate;
forming silicon carbide seed regions on the exposed regions of the silicon substrate;
consuming the masking layer at an elevated temperature;
growing monocrystalline 3C-SiC layers on the silicon carbide seed regions; and
forming regions of polycrystalline and/or amorphous 3C-SiC between the monocrystalline 3C-SiC layers on the heavily doped silicon region of the silicon substrate.

The masking layer may be any one of: a dielectric material; a silicon dioxide layer; a thermal oxide layer; a layer of semiconductor or conductive material; and a layer of polycrystalline silicon.

The masking layer may be fully consumed using a temperature of 1370° C.

The collector region may be formed from the monocrystalline 3C-SiC layers. The polycrystalline and/or amorphous 3C SiC regions are located next to the IGBT device structure as a grid.

The collector region may comprise 3C-SiC material which is doped using aluminium ion implant.

The thickness of the collector region may be about 2 μm.

The drift region, body region and emitter region each may comprise 3C-SiC material.

The thickness of the drift region may be about 8 μm.

Each of the collector region, the drift region, the body region and the emitter region may be an epitaxial region.

The method may further comprise back-grinding the silicon substrate up to the silicon region.

The method may further comprise forming a plurality of spots of oxide formed on the collector region.

The method may further comprise growing polycrystalline SiC through the spots of oxide.

The method may further comprise diffusing aluminium ion implant through the polycrystalline SiC from a bottom to top direction to form a vertical column of aluminium-doped polycrystalline SiC.

According to a further aspect of the present invention, there is provided a silicon carbide (SiC) based insulated gate bipolar transistor (IGBT) comprising: a monocrystalline silicon substrate having a principal substrate, wherein the silicon substrate is of a second conductivity type; a collector region of a first conductivity type, opposite to the second conductivity type, disposed over the principal surface of the silicon substrate, wherein the collector region comprises a material comprising 3-step cubic silicon carbide (3C-SiC); a semiconductor drift region of the second conductivity type disposed on the collector region; a body region of the first conductivity type located within the semiconductor drift region; an emitter region of the second conductivity type located within the body region; and a gate region placed above and in contact to the emitter region to form a channel region between the emitter region and the drift region through the body region; wherein the silicon substrate comprises a heavily doped silicon region of the first conductivity type near the principal surface of the silicon substrate and wherein the heavily doped silicon region within the silicon substrate comprises an aluminium ion implantation.

The depth of the heavily doped silicon region from the principal surface into the silicon substrate may be at least about 100 μm.

The depth of the heavily doped silicon region from the principal surface into the silicon substrate may be at least about 150 μm.

The temperature under which the heavily doped silicon region may be grown is at least about 1300° C. The dose of the aluminium ion implantation may be about 10¹⁷ cm⁻².

The collector region may form from the monocrystalline 3C-SiC layers disposed directly on the principal surface of the silicon substrate and polycrystalline and/or amorphous 3C-SiC layers between the monocrystalline 3C-SiC layers disposed directly on the principal surface of the silicon substrate. The polycrystalline and/or amorphous 3C-SiC layers do not form part of the collector region but they are located adjacent the collector region.

The collector region may be disposed directly on the further 3C-SiC layer.

The collector region may comprise 3C-SiC material comprising aluminium ion implantation.

The thickness of the collector region may be about 2 μm.

The drift region, body region and emitter region may each comprise 3C-SiC material.

The thickness of the drift region may be about 8 μm.

Each of the collector region, the drift region, the body region and the emitter region may be an epitaxial region.

The IGBT may further comprise a vertical column of aluminium doped polycrystalline SiC formed on the collector region.

### BRIEF DESCRIPTION OF THE DRAWINGS

The present disclosure will be understood more fully from the detailed description that follows and from the accompanying drawings, which however, should not be taken to limit the invention to the specific embodiments shown, but are for explanation and understanding only.

FIG. 1 illustrates a 3C-SiC based IGBT;

FIG. 2 illustrates the silicon substrate of the IGBT of FIG. 1;

FIG. 3 illustrate a portion of the IGBT of FIG. 1;

FIG. 4 illustrates an alternative portion of the IGBT of FIG. 1;

FIGS. 5 (a) to 5 (c) show the manufacturing steps of the additional 3C-SiC layer of FIG. 1; and

FIG. 6 illustrates a flow diagram of the method of manufacturing the IGBT of FIG. 1.

### DETAILED DESCRIPTION OF THE PREFERRED EMBODIMENTS

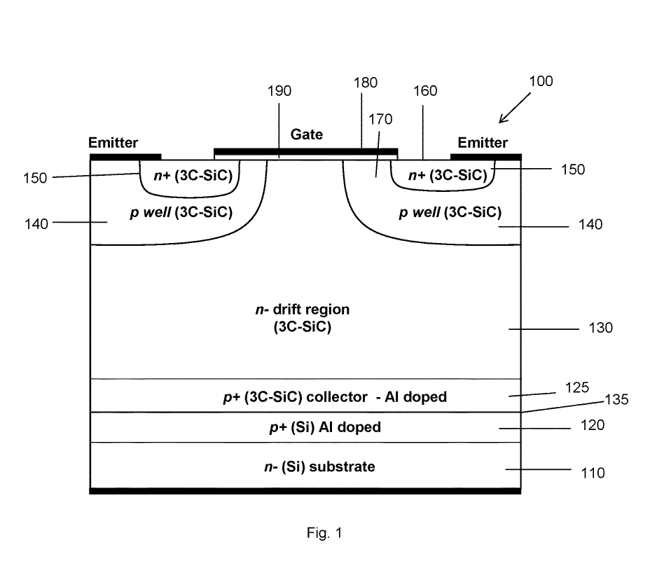

Referring to FIG. 1, an example of a vertical power semiconductor transistor 100 in the form of an insulated gate bipolar transistor (IGBT) is shown. The transistor 100 includes lightly doped n-type silicon substrate 110. The doping concentration of the n-type silicon substrate 110 is about from 10¹⁹ cm⁻³ to 10²¹ cm⁻³. The width and/thickness of the n-type silicon substrate is about 1 mm. The n-type substrate 110 includes a principal substrate 135. A highly doped p+ silicon region 120 is epitaxially grown near the principal surface 135 of the n-type silicon substrate 110. The silicon region 120 extends towards the substrate 110 from the principal surface. The silicon region 120 is doped using aluminum (Al) ion implant. Al diffuses much faster than boron, but the growth process may go up to about 1300° C. For example, a two hour diffusion can give a junction depth in excess of 150 μm from an Al implant dose of 10¹⁷ cm⁻².

The Al doped p+ silicon region 120 within the n-type silicon substrate 110 and near the principal surface of the n-type silicon substrate 110 is generally about 100 μm. The Al doped p+ silicon region 120 is generally extended from the principal surface 135 into the n-type substrate 110. It will be appreciated that the Al ion implant can use a plasma implant technique from Ion Beam Systems to great advantage in producing very high dose implants.

In FIG. 1, on top of the principal surface a p+ collector region 125 is epitaxially grown. The p+ collector region 125 includes 3C-SiC material. The p+ collector region 125 generally includes a monocrystalline 3C-SiC material. The p+ collector region 125 is doped using Al and it is generally about 2 μm thick. The doping concentration of the p+ collector region is about 10²¹ cm⁻³.

In one embodiment, the collector region 125 forms part of a monocrystalline SiC layer. The monocrystalline SiC layer (or the collector region 125) is spaced apart by a grid of polycrystalline SiC layers. The spaced apart arrangement of the monocrystalline SiC layer (or the collector region 125) and the polycrystalline SiC layer generally helps to reduce wafer bow between the p+ silicon region 120 and p+ collector region 125.

In the embodiment of FIG. 1, a lightly-doped n-type layer 130 which provides a drift region and which is supported on the p-type silicon carbide collector layer 130. P-type wells 140 at a surface 160 of the drift region 130 (or the IGBT) provide body regions 140. The drift region 130 includes 3C-SiC material. N-type wells 150 within the p-type wells 140 provide contact regions and provide emitters. The body region 140 and the contact region (emitters) 150 can be formed using 3C-SiC material. A channel 170 is formed beneath a gate 180 which is separated using a gate dielectric layer 190. Both the gate 180 and dielectric layer 190 form a gate region.

The IGBT shown in FIG. 1 is able to support much greater breakdown voltages due to the use of 3C-SiC in the epitaxial drift region 130. At the same time the on-resistance of the 3C-SiC IGBT can be significantly lower than the 4H-SiC IGBT. This is because a better channel mobility is observed in 3C-SiC (compared to 4H-SiC) and therefore the on-resistance of the channel region formed between the drift region 130 and the emitter region 150 can be significantly reduced.

It will be appreciated that a hetero-structure is formed between the p+ silicon region 120 within the n− type substrate 110 and p+3C-SiC layer 125. The 3C-SiC material in the first epitaxial layer 125 (˜2 microns) just above the SiC/Si interface 200 is very heavily defective because of the lattice miss-match between the two materials and heavily doped with Al as-grown, consequently this defective region is very conductive. In this way the heterojunction structure and consequent potential barriers can be overcome by becoming a quasi-metallic interface due to the presence of the dislocations, Al doping during epitaxial growth and Aluminium up-diffusion from the Si substrate.

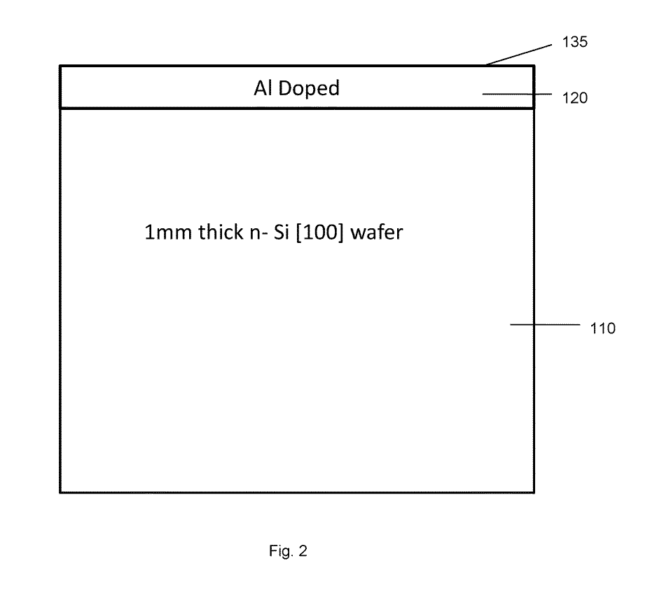

FIG. 2 illustrates the silicon substrate of the IGBT of FIG. 1. The silicon substrate 110 includes two portions: a lowly doped n-type silicon region 110 and a heavily doped p+ silicon region 120. The heavily doped p+ silicon region 120 is doped using Al ion implant driven in under a temperature about 1300° C. The thickness of the lowly doped n-type silicon region 110 is about 1 mm and the thickness of the heavily doped p+ silicon region 120 is about 80 to 120 μm, more preferably about 100 μm.

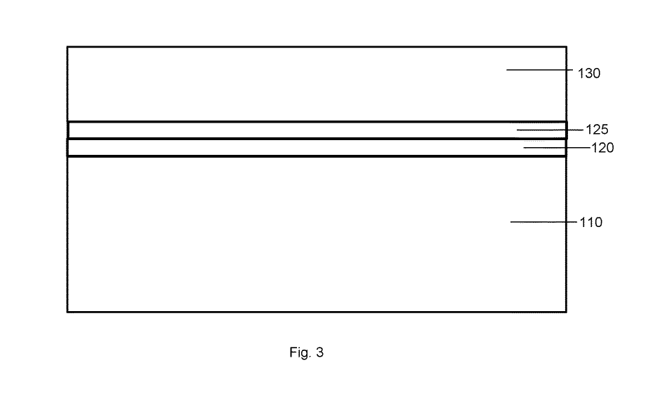

FIG. 3 illustrate a portion of the IGBT of FIG. 1. This figure illustrates that the n-type substrate 110 includes a heavily doped p+ silicon region 120 which is Al ion implanted. On top of the p+ silicon region 120 an Al doped collector region 125 is grown. The collector region 125 includes 3C-SiC material. The thickness of the collector region 125 is generally 2 μm. On top of the collector region 125, the drift region 130 is epitaxially grown. The thickness of the drift region is generally about 8 μm or more.

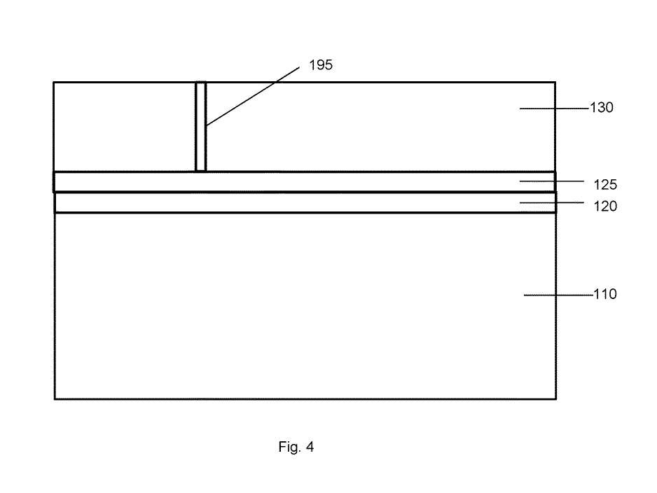

FIG. 4 illustrates an alternative portion of the IGBT of FIG. 1. In order to test the device at wafer level, small spots, for example 50-100 μm, of grid SiO₂ on the surface of the Si substrate 110 before epitaxy, close to the IGBT such that polySiC in these regions is grown. In this case Al diffuses through the polySiC very rapidly from bottom to top to form a vertical column 195. It is possible to add the standard p+ diffusions in the top to have a temporary top contact to the p+ region.

After building the device the Si wafer 110 is back grinded to 100 microns to reveal the p+ diffusion 120 to allow the back electrical contact provided for packaging. A die assembly process called “Dice before Grind” can be employed for this. It is possible to achieve about 100 micron grooves in the top/device side of the wafer and then flip it over and grind back until the die are separated. One advantage of this process is that it avoids the wafer-bowing problems that is encountered if a complete SiC/Si wafer is thinned out. It also demonstrates that ˜100 micron thick die are feasible in the 3C-SiC technology. The “Dice before Grind” is a Disco Corporation proprietary process.

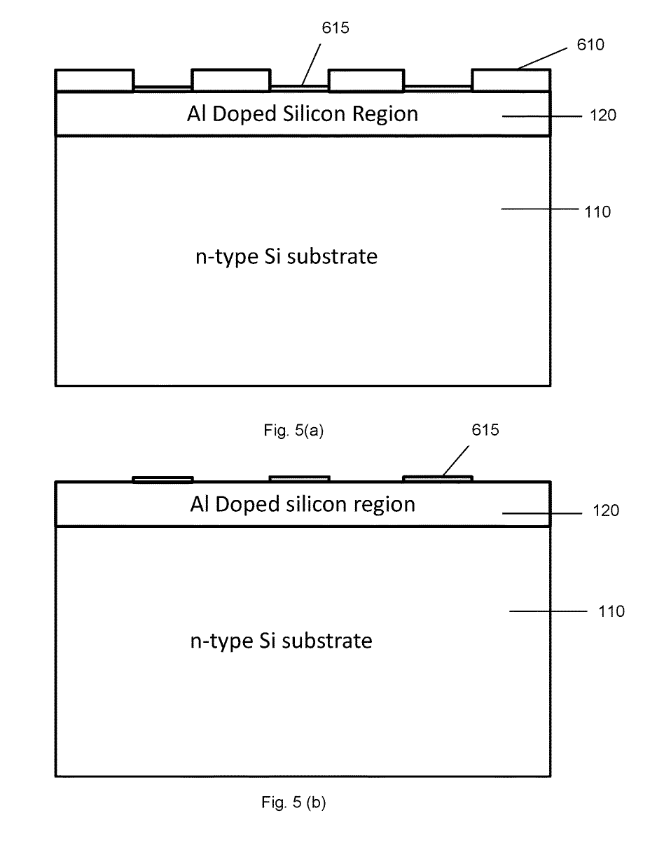

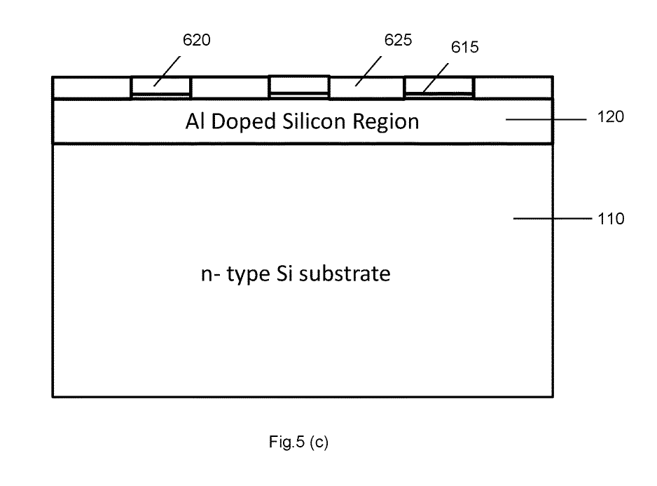

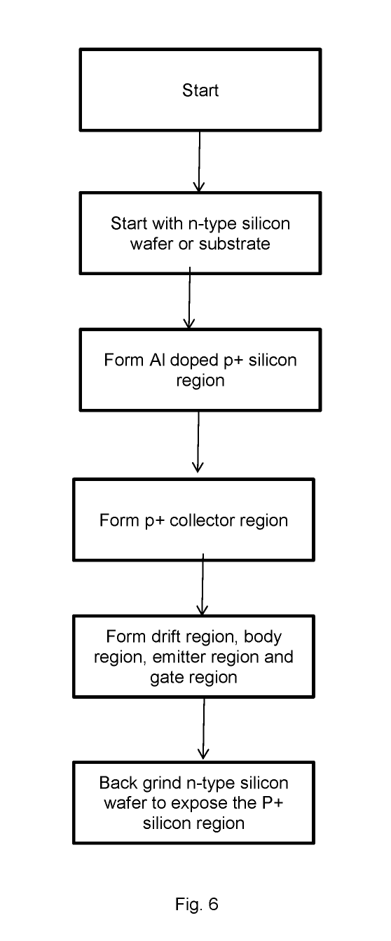

FIGS. 5 (a) to 5 (c) show the manufacturing steps of the collector region of FIG. 1. In FIG. 5 (a), silicon carbide seed layers 615 are grown between masking layers 610. In FIG. 6 (b), at an elevated temperature of 1370° C. and at a hydrogen rich atmosphere, the masking layers 610 are (fully) consumed. In the step of FIG. 6 (c), 3C SiC layers are formed in such a way that monocrystalline 3C-SiC layers 620 are formed on the seed layer 615 and polycrystalline and/or amorphous 3C-SiC layers 625 are formed (directly) on the Al doped silicon region 120. This type of grid of monocrystalline and polycrystalline and/or amorphous SiC layers help to reduce wafer bow after the wafer is cooled down. The monocrystalline 3C-SiC layer 620 then forms the collector region 125 of FIG. 1. The drift region 130, the body region 140, the emitter regoin 150 are subsequently formed only on the monocrystalline 3C-SiC layer 620 (but not on the polycrystalline SiC layer 625).

FIG. 6 illustrates a flow diagram of the method of manufacturing the IGBT of FIG. 1.

It will be appreciated that the first conductivity type refers to p type doping and the second conductivity type refers to n type doping. However, the doping concentration can be reversed as necessary.

Although the invention has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the invention, whether alone or in any appropriate combination with any other feature disclosed or illustrated herein.

1. A method of manufacturing a silicon carbide (SiC) based insulated gate bipolar transistor (IGBT), the IGBT comprising: a monocrystalline silicon substrate; a collector region of a first conductivity type disposed over the silicon substrate, wherein the collector region comprises a material comprising 3-step cubic silicon carbide (3C-SiC); a semiconductor drift region of a second conductivity type, opposite the first conductivity type, disposed on the collector region; a body region of the first conductivity type located within the semiconductor drift region; an emitter region of the second conductivity type located within the body region; a gate region placed above and in contact to the emitter region;
the method comprising:
providing the silicon substrate having a principal surface,
wherein the silicon substrate is of the second conductivity type;
doping the principal surface of the silicon substrate using an aluminium ion implant; and
driving the aluminium ion implant into the silicon substrate to a predetermined depth under a predetermined temperature so that a heavily doped silicon region of the first conductivity type is formed near the principal surface within the silicon substrate.

2. A method according to claim 1, wherein the principal surface of the silicon substrate is doped using a heavy aluminium ion implant.

3. A method according to claim 1, wherein the predetermined depth of the heavily doped silicon region from the principal surface into the silicon substrate is at least about 100 μm.

4. A method according to claim 1, wherein the predetermined depth of the heavily doped silicon region from the principal surface into the silicon substrate is at least about 150 μm.

5. A method according to claim 1, wherein the predetermined temperature under which the heavily doped silicon region is grown is at least about 1300° C.

6. A method according to claim 1, wherein the aluminium ion implant dose is about 10¹⁷ cm⁻².

7. A method according to claim 1, further comprising:
providing a masking layer on the principal surface of the silicon substrate, the masking layer having windows which expose corresponding regions of the heavily doped silicon region of the silicon substrate;
forming silicon carbide seed regions on the exposed regions of the silicon substrate;
consuming the masking layer at an elevated temperature;
growing monocrystalline 3C SiC layers on the silicon carbide seed regions; and
forming regions of polycrystalline and/or amorphous 3C SiC between the monocrystalline 3C SiC layers on the heavily doped silicon region of the silicon substrate.

8. A method according to claim 7, wherein the masking layer is any one of:
a dielectric material;
a silicon dioxide layer;
a thermal oxide layer;
a layer of semiconductor or conductive material;
a layer of polycrystalline silicon.

9. A method according to claim 7, wherein the masking layer is fully consumed using a temperature of 1370° C.

10. A method according to claim 7, wherein the collector region is formed from the monocrystalline 3C SiC layers.

11. A method according to claim 1, wherein the collector region comprises 3C-SiC material which is doped using aluminium ion implant.

12. A method according to claim 11, wherein the thickness of the collector region is about 2 μm.

13. A method according to claim 1, wherein the drift region, body region and emitter region each comprise 3C-SiC material.

14. A method according to claim 1, wherein the thickness of the drift region is about 8 μm.

15. A method according to claim 1, wherein each of the collector region, the drift region, the body region and the emitter region is an epitaxial region.

16. A method according to claim 1, further comprising back-grinding the silicon substrate up to the heavily doped silicon region.

17. A method according to claim 1, further comprising forming a plurality of spots of oxide formed on the collector region.

18. A method according to claim 17, further comprising growing polycrystalline SiC through the spots of oxide.

19. A method according to claim 18, further comprising diffusing aluminium ion implant through the polycrystalline SiC from a bottom to top direction to form a vertical column of aluminium doped polycrystalline SiC.

20. A silicon carbide (SiC) based insulated gate bipolar transistor (IGBT) comprising:
a monocrystalline silicon substrate having a principal substrate, wherein the silicon substrate is of a second conductivity type;
a collector region of a first conductivity type, opposite to the second conductivity type, disposed over the principal surface of the silicon substrate, wherein the collector region comprises a material comprising 3-step cubic silicon carbide (3C-SiC);
a semiconductor drift region of the second conductivity type disposed on the collector region;
a body region of the first conductivity type located within the semiconductor drift region;
an emitter region of the second conductivity type located within the body region; and
a gate region placed above and in contact to the emitter region to form a channel region between the emitter region and the drift region through the body region;
wherein the silicon substrate comprises a silicon region of the first conductivity type near the principal surface of the silicon substrate and wherein the silicon region within the silicon substrate comprises an aluminium ion implantation.

21. An IGBT according to claim 20, wherein the depth of the heavily doped silicon region from the principal surface into the silicon substrate is at least about 100 μm.

22. An IGBT according to claim 20, wherein the depth of the heavily doped silicon region from the principal surface into the silicon substrate is at least about 150 μm.

23. An IGBT according to claim 20, wherein the temperature under which the heavily doped silicon region is grown is at least about 1300° C.

24. An IGBT according to claim 20, wherein the dose of the aluminium ion implantation is about 10¹⁷ cm⁻².

25. An IGBT according to claim 20, wherein the collector region comprises monocrystalline 3C SiC layers disposed directly on the principal surface of the silicon substrate.

26. An IGBT according to claim 20, wherein the collector region comprises 3C-SiC material comprising aluminium ion implantation.

27. An IGBT according to claim 20, wherein the thickness of the collector region is about 2 μm.

28. An IGBT according to claim 20, wherein the drift region, body region and emitter region each comprise 3C-SiC material.

29. An IGBT according to claim 20, wherein the thickness of the drift region is about 8 μm.

30. An IGBT according to claim 20, wherein each of the collector region, the drift region, the body region and the emitter region is an epitaxial region.

31. An IGBT according to claim 20, further comprising a vertical column of aluminium doped polycrystalline SiC formed on the collector region.
